(19) United States
(12) Patent Application Publication
(10) Pub. No.: US 2025/0332682 A1
(43) Pub. Date: Oct. 30, 2025

(54) SUBSTRATE POLISHING APPARATUS AND FILM THICKNESS CALCULATING METHOD

(71) Applicant: EBARA CORPORATION, Tokyo (JP)

(72) Inventors: Yuta SUZUKI, Tokyo (JP); Keita YAGI, Tokyo (JP)

(21) Appl. No.: 19/186,465

(22) Filed: Apr. 22, 2025

(30) Foreign Application Priority Data
Apr. 25, 2024 (JP) 2024-071341

(51) Int. Cl. B24B 37/013; H01L 21/3105; H01L 21/66

(52) U.S. Cl. CPC B24B 37/013; H01L 21/31053; H01L 22/26

(57) ABSTRACT

An object is to accurately measure, during polishing of a substrate, thickness of a film which is an object of polishing.

A substrate polishing apparatus comprises: a polishing table which is provided with an eddy current sensor and is constructed to be able to be rotated; a polishing head which is positioned to be opposite to the polishing table, is constructed to be able to be rotated, and allows a substrate to be attached to a surface which is positioned to be opposite to the plating table, and a controller. The controller is constructed to obtain waveform data of output signals of the eddy current sensor during polishing of the substrate; detect minimum points or maximum points in the waveform data; correct, based on the detected minimum points or the detected maximum points, the waveform data; and calculate, based on the corrected waveform data, thickness of a film on a surface of the substrate.

### CROSS REFERENCE TO RELATED APPLICATION

This document claims priority to Japanese Patent Application No. 2024-071341 filed Apr. 25, 2024, the entire contents of which are hereby incorporated by reference.

### TECHNICAL FIELD

The present invention relates to a substrate polishing apparatus and a film thickness calculating method.

### BACKGROUND ART

There is a CMP (Chemical Mechanical Polishing) apparatus in apparatuses for manufacturing semiconductor devices. A representative CMP apparatus comprises a polishing table to which a polishing pad is attached, and a polishing head to which a substrate is attached. In the representative CMP apparatus, a substrate is polished by supplying a polishing liquid to the polishing pad, and rotating, in the state that the polishing pad and the substrate are in contact with each other, at least one of the polishing table and the polishing head.

### CITATION LIST

### Patent Literature

PTL 1: Japanese Patent Application Public Disclosure No. 2021-058955

### SUMMARY OF INVENTION

### Technical Problem

It is possible to use an eddy current sensor for measuring thickness of a film which is an object to be polished, during polishing of a substrate. The eddy current sensor is installed in a polishing table, for example. The eddy current sensor moves along a path on a surface of a substrate while a polishing table is being rotated, and measures film thickness at respective points on the path (for example, refer to Patent Literature 1). However, in the case that a metal structure, which has been arranged locally in a substrate, exists in addition to a film (a metal film) which is a to-be-polished object, it becomes difficult, due to an effect therefrom, to accurately measure thickness, that should be measured originally, of the film which is the to-be-polished object.

### Solution to Problem

According to an embodiment, a substrate polishing apparatus is provided; and the substrate polishing apparatus comprises: a polishing table which is provided with an eddy current sensor and is constructed to be able to be rotated; a polishing head which is positioned to be opposite to the polishing table, is constructed to be able to be rotated, and allows a substrate to be attached to a surface which is positioned to be opposite to the plating table; and a controller: wherein the controller is constructed to obtain waveform data of output signals of the eddy current sensor during polishing of the substrate; detect minimum points or maximum points in the waveform data; correct, based on the detected minimum points or the detected maximum points, the waveform data; and calculate, based on the corrected waveform data, thickness of a film on a surface of the substrate.

### BRIEF DESCRIPTION OF DRAWINGS

FIG. 1 is a front view of a substrate polishing apparatus according to an embodiment.

FIG. 2 is a cross-sectional schematic diagram showing a structure of an example substrate which is an object to be polished by a substrate polishing apparatus.

FIG. 3 is a flow chart showing an algorithm of a method according to an embodiment of the present invention.

FIG. 4 is an explanatory drawing for a correction process for waveform data in an output signal of an eddy current sensor.

FIG. 5 is a flow chart showing an algorithm of a method according to a different embodiment of the present invention.

FIG. 6 is a schematic diagram which explains the concept of a prominence.

FIG. 7 is an explanatory drawing for a correction process for waveform data in an output signal of an eddy current sensor.

### DESCRIPTION OF EMBODIMENTS

In the following description, embodiments of the present invention will be explained with reference to the figures. In the figures that will be explained in the following description, a reference symbol assigned to one component is also assigned to the other component if the other component is the same as or corresponds to the one component, and overlapping explanation of these components will be omitted.

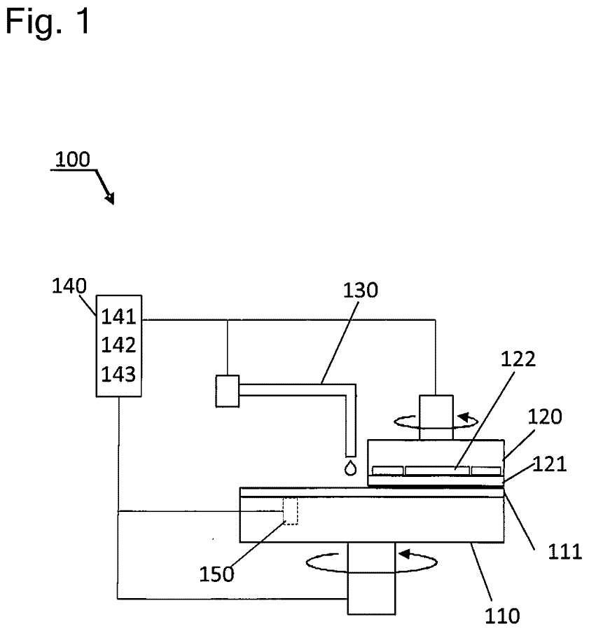

FIG. 1 is a front view of a substrate polishing apparatus 100 according to an embodiment. The substrate polishing apparatus 100 shown in FIG. 1 is a CMP (Chemical Mechanical Polishing) apparatus. It should be reminded that the substrate polishing apparatus 100 is not limited to a CMP apparatus. The substrate polishing apparatus 100 may be any apparatus which polishes a substrate by rotating a polishing table in which an eddy current sensor has been installed.

The CMP apparatus 100 comprises a polishing table 110, a polishing head 120, and a liquid supplying mechanism 130. The CMP apparatus 100 may further comprise a storage device 141, a processor 142, and an input/output device 143, for example.

A polishing pad 111 is installed in an attachable/detachable manner on a top surface of the polishing table 110. In this regard, the top surface of the polishing table 110 refers to a surface, in the polishing table 110, opposite to the polishing head 120. Accordingly, the top surface of the polishing table 110 is not limited to a surface in a position in a vertically upward direction. The polishing head 120 is installed in such a manner that it is in a position opposite to the polishing table 110. A substrate 121 is attached in an attachable/detachable manner to a surface which is in the polishing head 120 and positioned to be opposite to the polishing table 110. The liquid supplying mechanism 130 is constructed to supply a polishing liquid such as slurry or the like to the polishing pad 111. In this regard, the liquid supplying mechanism 130 may be constructed to supply a cleaning liquid, a chemical solution, or the like, in addition to the polishing liquid.

The CMP apparatus 100 may bring the substrate 121 into contact with the polishing pad 111, by moving the polishing head 120 downward by operating an up-and-down motion mechanism which is not shown in the figures. In this regard, the up-and-down motion mechanism may be able to move the polishing table 110 upward and downward. The polishing table 110 and the polishing head 120 are rotated by motors or the like which are not shown in the figures. The CMP apparatus 100 polishes the substrate 121 by rotating, in the state that the substrate 121 and the polishing pad 111 are in contact with each other, both the polishing table 110 and the polishing head 120.

The CMP apparatus 100 may further comprise an air bag 122 which is partitioned into multiple concentric circular sections. The air bag 122 may be installed in the polishing head 120. Additionally or alternatively, the air bag 122 may be installed in the polishing table 110. The air bag 122 is a member for adjusting a polishing pressure with respect each of regions in the substrate 121. The air bag 122 is constructed in such a manner that it changes its volume according to the pressure of air introduced into the inside thereof. A fluid other than the air, for example, a nitrogen gas or pure water, may be introduced into the air bag 122.

An eddy current sensor 150 is installed in the inside of the polishing table 110. The eddy current sensor 150 is installed in a position such that the eddy current sensor 150 passes the center of the substrate 121 when the polishing table 110 is rotated during polishing. The eddy current sensor 150 is constructed to induce eddy current in an electrically conductive layer on the surface of the substrate 121. The eddy current sensor 150 is further constructed to output, in response to change in impedance due to a magnetic field generated by the eddy current, a signal corresponding to the thickness of the electrically conductive layer on the surface of the substrate 121. By using the output signal from the eddy current sensor 150, the film thickness of the film, which is the to-be-polished object, on the surface of the substrate 121 can be obtained.

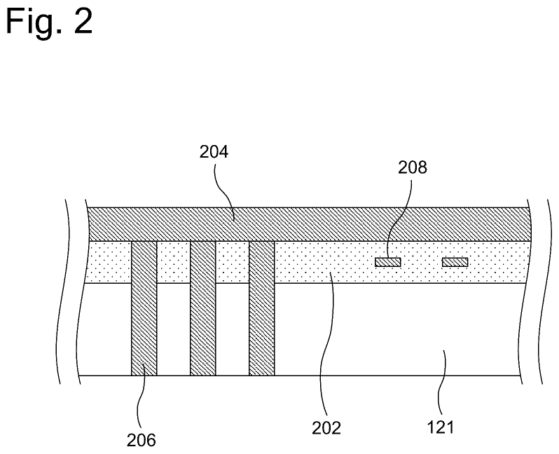

It should be reminded that the matter which influences the output signal of the eddy current sensor 150 is not limited to a film which is exposed on the topmost surface of the substrate 121 (a film formed over the whole topmost surface of the substrate 121) and is a to-be-polished object. FIG. 2 is a cross-sectional schematic diagram showing a structure of an example substrate 121 which is an object to be polished by the substrate polishing apparatus 100. As shown in FIG. 2, a dielectric film (for example, a film comprising SiO₂ or the like) 202 is formed on the whole top surface of the example substrate 121, and, further, a metal film (for example, a film comprising Cu or the like) 204 is formed above the dielectric film 202 to cover it. The metal film 204 is a film which is positioned on the topmost surface of the substrate 121 and is a to-be-polished object. Further, the substrate 121 may comprise one or multiple through-electrodes 206 which allow electrical conduction between one surface and the other surface of the substrate 121. Further, a metal wire 208 may be embedded in the dielectric film 202 on the substrate 121. When the eddy current sensor 150 passes a position above or close to a through-electrode 206 or a metal wire 208 such as that explained above, eddy current is induced by the above metal structure, and the output signal of the eddy current sensor is influenced thereby; and, accordingly, the value of the signal changes from that of an output signal of the eddy current sensor 150 obtained when the eddy current sensor 150 has passed a region on the substrate 121 where no trough-electrode 206 and no metal wire 208 exists. That is, the through-electrode 206 or the metal wire 208 which is a metal structure formed locally in the substrate 121 may become a cause of generation of noise in an output signal of the eddy current sensor 150. It should be reminded that the metal structures are not limited to the through-electrode 206 and the metal wire 208 embedded in the dielectric film 202 which have been explained above, and, in addition thereto, they may also include a wire and a via exposed on the topmost surface of the substrate 121, for example.

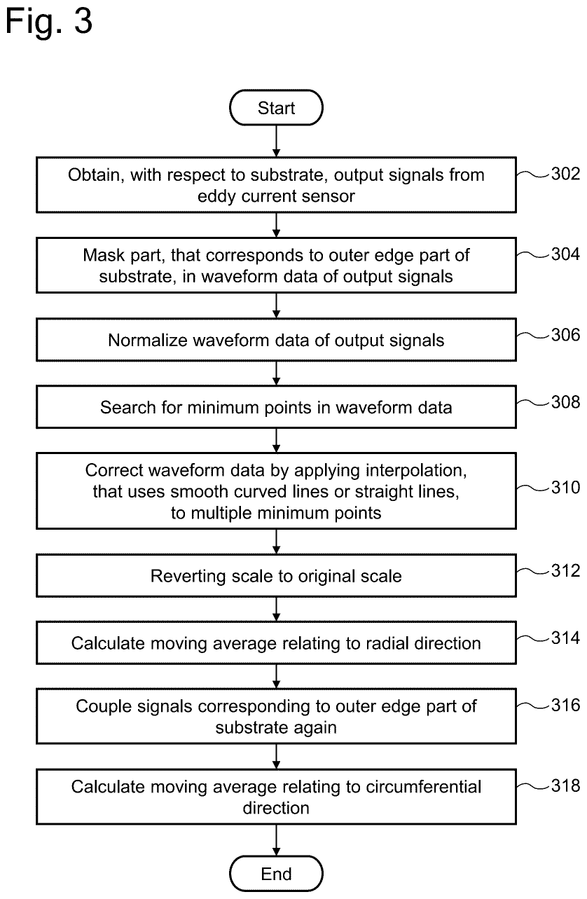

FIG. 3 is a flow chart showing an algorithm of a film thickness calculating method according to an embodiment of the present invention, that makes it possible to remove or reduce noise that is generated due to a metal structure locally positioned in the substrate 121 and is included in an output signal of the eddy current sensor 150. The process in the present flow chart may be implemented by a processor (for example, the processor 142 in the controller 140).

First, in step 302, with respect to the substrate 121, output signals of the eddy current sensor 150 are obtained. Specifically, output signals are obtained from the eddy current sensor 150 while both the polishing head 120, to which the substrate 121 which is the to-be-polished object has been attached, and the polishing table 110 are rotated at respective predetermined rotation speeds. With respect to the substrate 121 (i.e., when viewed from the substrate 121), the eddy current sensor 150 moves on an arc-shaped path corresponding to the ratio between the rotation speed of the polishing table 110 and the rotation speed of the polishing head 120. During each single rotation of the polishing table 110, the eddy current sensor 150 crosses the surface of the substrate 121 along an ark-shaped path having a predetermined curvature that is determined based on the rotation speeds of the polishing table 110 and the polishing head 120; and, during a next single rotation of the polishing table 110, the eddy current sensor 150 passes a path corresponding to a different arc that is an arc having a curvature that is the same as the curvature in the case of the last single revolution. Accordingly, signal values at respective points on the multiple ark-shaped paths are obtained successively from the eddy current sensor 150. In the following description, a series of signal values that is obtained from the eddy current sensor 150 when it has passed one of paths on the substrate 121 will be referred to as “a profile” or “waveform data” of the output signals of the eddy current sensor 150.

Next, in step 304, in the profile (waveform data) of the output signals of the eddy current sensor 150 obtained in step 302, parts corresponding to an outer edge part of the substrate 121 (for example, a belt-shaped region which has width extending from the edge to the inner side of the substrate 121 by several millimeters) are masked. This is because it is assumed that accuracy of measurement performed by the eddy current sensor 150 at the outer edge part of the substrate 121 is not good enough, and, accordingly, it is preferable to exclude, from objects of calculation that is performed later, the signal values obtained from the above part by the eddy current sensor 150.

Next, in step 306, the waveform data, that is in the state after completion of the process in step 304, is normalized. In this regard, the process in step 306 may be omitted.

Next, in step 308, minimum points in the waveform data, that was processed in step 306, are searched for. Regarding the minimum-point searching algorithm, an appropriate well-known method can be applied as the algorithm herein, and detailed explanation thereof will be omitted herein.

Next, in step 310, correction of the waveform data is performed based on the minimum points found in step 308. Specifically, multiple minimum points can be found in the waveform data in step 308, and, in step 310, the waveform data is corrected by applying interpolation, that uses smooth curved lines or straight lines, to the found multiple minimum points.

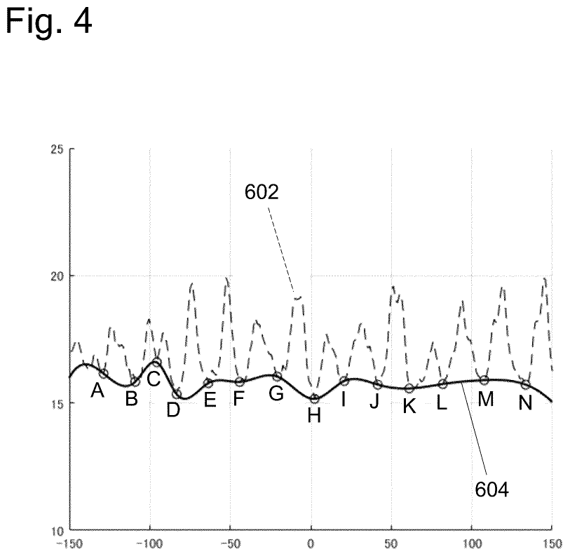

FIG. 4 shows, for explaining the correction process in step 310, an example of waveform data that is in the state before correction and an example of the waveform data that is in the state after correction. In a graph in FIG. 4, a horizontal axis represents positions on a path on which the eddy current sensor 150 moves (i.e., distances from the center of the substrate 121 to the center of the eddy current sensor 150), and a vertical axis represents values of signals from the eddy current sensor 150. In the example shown in FIG. 4, the waveform data 602, that is in the state before correction, has multiple minimum points A-N. By connecting these multiple minimum points A-N by using smooth curved lines or straight lines (i.e., by performing interpolation), the waveform data 604, that is in the state after correction, is formed. Regarding the method for connecting multiple points in a graph by smooth curved lines, a well-known method can be adopted as the method used herein, and detailed explanation thereof will be omitted herein.

It is highly likely that multiple peaks included in the waveform data are noise components originated from a metal structure(s) (the through-electrode 206 and/or the metal wire 208) which locally exists on the surface or in the inside of the substrate 121. Accordingly, by correcting, based on the minimum points in the waveform data, the waveform data in steps 308 and 310, the noise that is generated due to a metal structure locally positioned in the substrate 121 and is included in the output signal of the eddy current sensor 150 can be removed or reduced.

Next, in step 312, for reverting the values that have been normalized in step 306 to values in the original scale, the waveform data, that is in the state after correction that was made in step 310, is multiplied by a reciprocal number of the ratio by which the values of signals from the eddy current sensor 150 were multiplied when they were normalized. In this regard, the process in step 312 can be omitted in the case that above-explained step 306 is omitted.

Next, in step 314, with respect to the waveform data that is in the state after completion of the process in step 312, a moving average, that relates to the direction along the path on which the eddy current sensor 150 moved (i.e. the moving average relating to the direction of the horizontal axis in the graph in FIG. 4), is calculated.

Next, in step 316, the signal values, that correspond to the outer edge part of the substrate 121 and have been masked in step 304, are coupled again to the waveform data that is in the state after completion of the process in step 314.

Next, in step 318, a moving average of multiple pieces of the waveform data, that are in the state after completion of the process in step 316, with respect to multiple paths which are adjacent to one another and on which the eddy current sensor 150 moved is calculated. In this regard, obtaining the moving average in step 314 corresponds to obtaining a moving average relating to a radial direction of the substrate 121, and obtaining the moving average in step 318 corresponds to obtaining a moving average relating to a circumferential direction of the substrate 121. By performing the above moving average processes, small noise existing in the waveform data in the output signals of the eddy current sensor 150 can be removed.

By adopting the above construction, it becomes possible to obtain film thickness distribution data, that is accurate and is not affected by the through-electrode 206 and the metal wire 208 in the substrate, in a radial direction of a substrate. By using the film thickness distribution data obtained during polishing of the substrate 121, the controller 140 can determine an end point of polishing accurately. In a different construction, by using the film thickness distribution data obtained during polishing of the substrate 121, the controller 140 may increase and decrease the internal pressure of the air bag 122 to thereby increase the polishing pressure applied to a region where the film thickness is thick (i.e. a region where progress in polishing is slow), and decrease the polishing pressure applied to a region where the film thickness is thin (i.e. a region where progress in polishing is fast). By performing the above control, the film thickness of the substrate 121 can be made uniform.

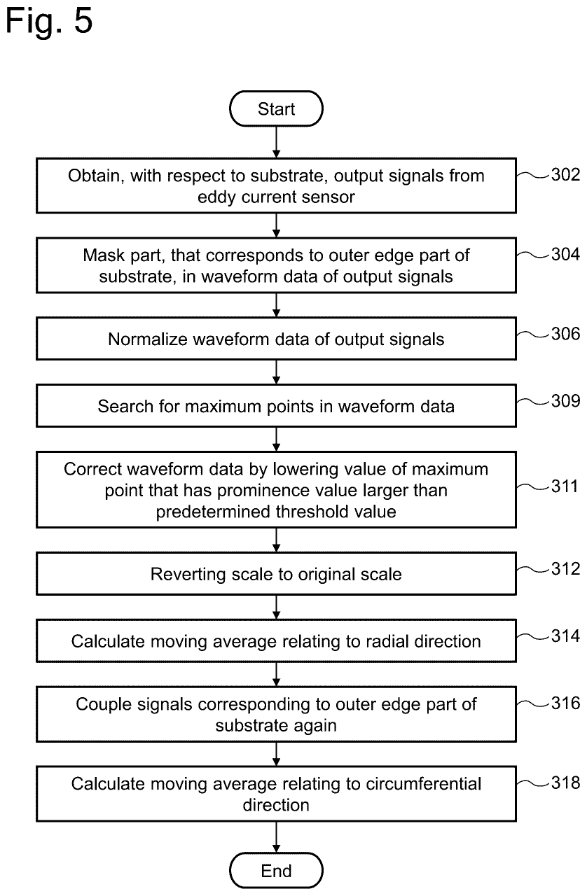

FIG. 5 is a flow chart showing an algorithm of a film thickness calculating method according to a different embodiment of the present invention, that makes it possible to remove or reduce noise that is generated due to a metal structure locally positioned in the substrate 121 and is included in an output signal of the eddy current sensor 150. The process in the present flow chart may be implemented by a processor (for example, the processor 142 in the controller 140). Steps 302-306 and steps 312-318 in the algorithm according to the present embodiment are the same as those in the above-explained embodiment in FIG. 3, and overlapping explanation of these steps will be omitted.

In step 309 that follows step 306, maximum points are searched for in the waveform data that is in the state after completion of the process in step 306. Regarding the maximum-point searching algorithm, an appropriate well-known method can be applied as the algorithm herein, and detailed explanation thereof will be omitted herein.

Next, in step 311, based on the maximum points found in step 309, correction of the waveform data is performed. Specifically, multiple maximum points can be found in the waveform data in step 309, and, in step 311, a prominence is calculated with respect to each of the found multiple maximum points. Thereafter, in relation to a maximum point that has a prominence value larger than a predetermined threshold value, the values of the maximum point and points adjacent thereto are lowered to thereby correct the waveform data.

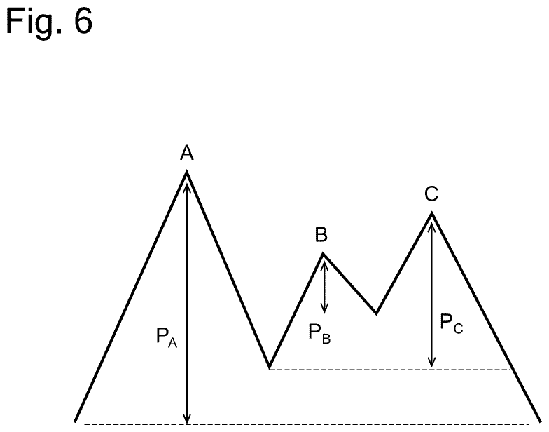

In this regard, a “prominence” has been known as an index that represents, with respect to a peak (a maximum peak) that is paid attention to in multiple peaks, the degree of “conspicuousness (i.e., prominence)” of the peak. FIG. 6 is a schematic diagram which explains, in a simplified form, the concept of a prominence. In FIG. 6, the prominences of peaks A, B, and C are defined as the heights PA, PB, and PC shown by vertical arrows in the figure, respectively. In this regard, more detailed explanation with respect to the prominence can be found by referring to information sources such as “https://jp.mathworks.com/help/signal/ug/prominence.html” and so on, Japanese Patent Application Public Disclosure No. 2023-101867, and so on, for example.

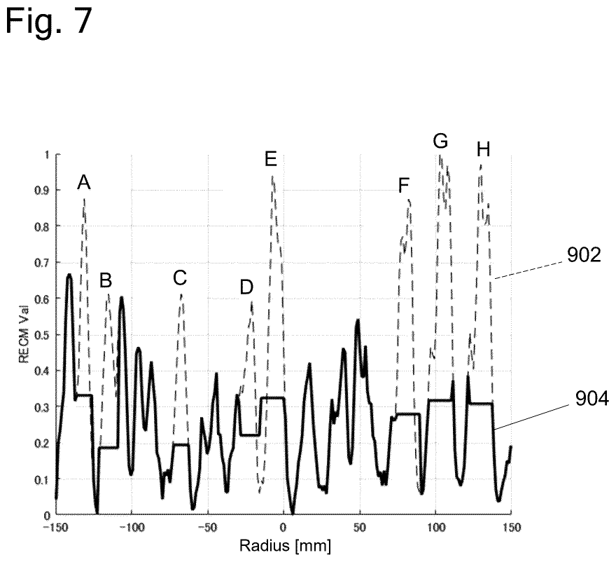

FIG. 7 is a figure which shows a tangible example of a correction process in step 311. In a graph in FIG. 7, a horizontal axis represents positions on a path on which the eddy current sensor 150 moves (i.e., distances from the center of the substrate 121 to the center of the eddy current sensor 150), and a vertical axis represents values of signals from the eddy current sensor 150. In the example shown in FIG. 7, the waveform data 902, that is in the state before correction, includes multiple maximum points; and some maximum points, specifically, maximum points A-H, in the multiple maximum points have prominences larger than a predetermined threshold value. In the waveform data 904 that is in the state after correction, the signal values of the maximum points (peaks) A-H and points adjacent thereto are changed to predetermined values that are smaller than the peak values of the peaks, respectively. For example, each predetermined value may be a value obtained by multiplying a peak value of each peak by a predetermined attenuation factor (for example, 30%). In this regard, the maximum points other than the maximum points A-H having prominence values larger than predetermined threshold values are not objects of correction, and they remain as they stand in the waveform data 904 in the state after correction.

As explained in relation to the embodiment in FIG. 3, it is highly likely that multiple peaks included in the waveform data are noise components originated from a metal structure(s) (the through-electrode 206 and/or the metal wire 208) which locally exists on the surface or in the inside of the substrate 121. Accordingly, by correcting, based on the maximum points in the waveform data, the waveform data in steps 309 and 311, the noise that is generated due to a metal structure locally positioned in the substrate 121 and is included in the output signal of the eddy current sensor 150 can be removed or reduced.

In the above description, embodiments of the present invention have been explained based on some examples; and, in this regard, the above-explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

100 Substrate polishing apparatus
110 Polishing table
111 Polishing pad
120 Polishing head
121 Substrate
122 Air bag
130 Liquid supplying mechanism
140 Controller
141 Storage device
142 Processor
143 Input/output device
150 Eddy current sensor
202 Dielectric film
204 Metal film
206 Through-electrode
208 Metal wire

What is claimed is:

1. A substrate polishing apparatus comprising:
a polishing table which is provided with an eddy current sensor and is constructed to be able to be rotated,
a polishing head which is positioned to be opposite to the polishing table, is constructed to be able to be rotated, and allows a substrate to be attached to a surface which is positioned to be opposite to the plating table, and
a controller; wherein
the controller is constructed to
obtain waveform data of output signals of the eddy current sensor during polishing of the substrate,
detect minimum points or maximum points in the waveform data,
correct, based on the detected minimum points or the detected maximum points, the waveform data, and
calculate, based on the corrected waveform data, thickness of a film on a surface of the substrate.

2. The substrate polishing apparatus as recited in claim 1, wherein the controller is constructed to
detect multiple minimum points in the waveform data, and
correct the waveform data by applying interpolation, that uses smooth curved lines or straight lines, to the detected multiple minimum points in the waveform data.

3. The substrate polishing apparatus as recited in claim 1, wherein the controller is constructed to
detect multiple maximum points in the waveform data,
calculate a prominence of each of the detected multiple maximum points,
judge whether the each calculated prominence is greater than a predetermined threshold value,
correct the waveform data by lowering values of each maximum point, that has been judged as that having a prominence larger than the predetermined threshold value, and points adjacent to the maximum point in the waveform data.

4. The substrate polishing apparatus as recited in claim 1, wherein the waveform data is data comprising a series of output signals obtained from the eddy current sensor when the eddy current sensor has passed one or multiple paths on a surface, which is an object of polishing, of the substrate.

5. The substrate polishing apparatus as recited in claim 1, wherein the substrate is a substrate having one or multiple metal structures which locally exist on the surface or in the inside of the substrate.

6. The substrate polishing apparatus as recited in claim 5, wherein the metal structure is a through-electrode or a metal wire formed on the substrate.

7. The substrate polishing apparatus as recited in claim 1 further comprising an air bag which is able to adjust polishing pressure applied to the substrate, wherein the controller is further constructed to control, based on the calculated thickness of the film on the substrate, internal pressure of the air bag.

8. A method for calculating thickness of a film in a substrate polishing apparatus, wherein the substrate polishing apparatus comprises;
a polishing table which is provided with an eddy current sensor and is constructed to be able to be rotated, and
a polishing head which is positioned to be opposite to the polishing table, is constructed to be able to be rotated, and allows a substrate to be attached to a surface which is positioned to be opposite to the plating table; and
the method comprises steps for
obtaining waveform data of output signals of the eddy current sensor during polishing of the substrate,
detecting minimum points or maximum points in the waveform data,
correcting, based on the detected minimum point or the detected maximum point, the waveform data, and
calculating, based on the corrected waveform data, thickness of a film on a surface of the substrate.

9. The method as recited in claim 8, wherein the step for correcting comprises a step for applying interpolation, that uses smooth curved lines or straight lines, to the detected multiple minimum points in the waveform data.

10. The method as recited in claim 8, wherein the step for correcting the waveform data comprises steps for
calculating a prominence of each of the detected multiple maximum points,
judging whether the each calculated prominence is greater than a predetermined threshold value,
lowering values of each maximum point, that has been judged as that having a prominence larger than the predetermined threshold value, and points adjacent to the maximum point in the waveform data.
